(19) United States
(12) Patent Application Publication
(10) Pub. No.: US 2025/0220930 A1
(43) Pub. Date: Jul. 3, 2025

(54) INTEGRATED CIRCUITS INCLUDING POLYSILICON RESISTORS

(71) Applicant: SAMSUNG ELECTRONICS CO., LTD., Suwon-si (KR)

(72) Inventors: Jungwon Choe, Suwon-si (KR); Jungseok Hwang, Suwon-si (KR); Seongjin Kim, Suwon-si (KR); Sunghoon Kim, Suwon-si (KR); Changbum Kim, Suwon-si (KR)

(21) Appl. No.: 18/956,876

(22) Filed: Nov. 22, 2024

(30) Foreign Application Priority Data
Jan. 3, 2024 (KR) 10-2024-0001070
Jan. 24, 2024 (KR) 10-2024-0011183

(51) Int. Cl. H01L 27/08

(52) U.S. Cl. CPC H10D 1/47; H10D 84/209

(57) ABSTRACT

An integrated circuit includes active regions on an upper surface of a semiconductor substrate and having no electrical connection on the semiconductor substrate, an isolation layer on the upper surface of the semiconductor substrate and defining the active regions, and polysilicon resistors on the active regions and the isolation layer. The polysilicon resistors extend in a second direction that is perpendicular to a first direction in which the active regions extend, and are configured such that the number of active regions overlapping each of the polysilicon resistors in a vertical direction is identical.

### CROSS-REFERENCE TO RELATED APPLICATION

This application is based on and claims priority under 35 U.S.C. § 119 to Korean Patent Application Nos. 10-2024-0001070, filed on Jan. 3, 2024, and 10-2024-0011183, filed on Jan. 24, 2024, in the Korean Intellectual Property Office, the disclosures of which are incorporated by reference herein in their entireties.

### BACKGROUND

The present disclosure relates to integrated circuits (ICs), and more particularly, to ICs including polysilicon resistors by which a leakage current of an IC is prevented, and the chip size is reduced.

An IC may include one or more semiconductor devices. As the sizes of semiconductor devices decrease, the sizes of circuit components of the semiconductor devices and the spacings between the circuit components also decrease. When the spacings between the circuit components decrease, a leakage current may occur between neighboring components.

To prevent a leakage current between devices, the devices may be designed to have a large spacing therebetween, but this may cause the chip size of the IC to increase.

### SUMMARY

The present disclosure provides integrated circuits including polysilicon resistors by which a leakage current of an integrated circuit (IC) is prevented and the chip size is reduced.

In a general aspect, an integrated circuit includes: a semiconductor substrate, active regions on an upper surface of the semiconductor substrate, the active regions having no electrical connection on the semiconductor substrate, an isolation layer on the upper surface of the semiconductor substrate and defining the active regions, and polysilicon resistors on the active regions and the isolation layer, the polysilicon resistors extending in a second direction that is perpendicular to a first direction in which the active regions extend, wherein the polysilicon resistors are configured such that a number of active regions overlapping each of the polysilicon resistors in a vertical direction is identical.

In another general aspect, an integrated circuit includes: a first conductive type of a semiconductor substrate, active regions on an upper surface of the semiconductor substrate, the active regions having no electrical connection on the semiconductor substrate, an isolation layer on the upper surface of the semiconductor substrate and defining the active regions, polysilicon resistors on the active regions and the isolation layer, the polysilicon resistors extending in a second direction that is perpendicular to a first direction in which the active regions extend, and a second conductive type of a well region, on the upper surface of the semiconductor substrate and arranged adjacent to the active regions, the well region including a first well region arranged at one side of the well region in the first direction and a second well region arranged at the other side of the well region in the first direction, wherein the active regions beneath the polysilicon resistors include first active regions overlapping the first and second well regions in the first direction and second active regions that are the remainder of the active regions, and each of the first active regions is cut at least once in the first direction such that the isolation layer is between the cut portions.

In another general aspect, an integrated circuit includes: a semiconductor substrate, active regions on an upper surface of the semiconductor substrate, the active regions having no electrical connection on the semiconductor substrate, an isolation layer on the upper surface of the semiconductor substrate and defining the active regions, polysilicon resistors on the active regions and the isolation layer, the polysilicon resistors extending in a second direction that is perpendicular to a first direction in which the active regions extend, and dummy polysilicon resistors on the upper surface of the semiconductor substrate and at the outer peripheries of the polysilicon resistors to be adjacent to both sides of the polysilicon resistors in the first direction, wherein each of the active regions beneath the polysilicon resistors and the dummy polysilicon resistors is cut at least once in the first direction such that the isolation layer is between the cut portions.

### BRIEF DESCRIPTION OF THE DRAWINGS

FIG. 1 is a conceptual block diagram illustrating an example of an integrated circuit.

FIGS. 2A, 2B, and 3 are views illustrating an example of an integrated circuit including polysilicon resistors. FIG. 2C is a graph showing a leakage current characteristic of the integrated circuit.

FIGS. 4A and 4B are views illustrating examples of polysilicon resistors. FIG. 4C is a graph showing a leakage current characteristic of the polysilicon resistor of FIGS. 4A and 4B.

FIGS. 5A and 5B are views illustrating examples of polysilicon resistors.

FIGS. 6A and 6B are views illustrating examples of polysilicon resistors.

FIGS. 7A and 7B are views illustrating examples of polysilicon resistors.

FIGS. 8A and 8B are views illustrating examples of polysilicon resistors.

FIGS. 9A and 9B are views illustrating examples of polysilicon resistors.

FIG. 10 is a view illustrating an example of a memory device.

FIG. 11 is a block diagram illustrating an example in which a memory device is applied to a solid state driver (SSD) system.

FIG. 12 is a block diagram of a system illustrating an example of an electronic apparatus including a memory device.

### DETAILED DESCRIPTION

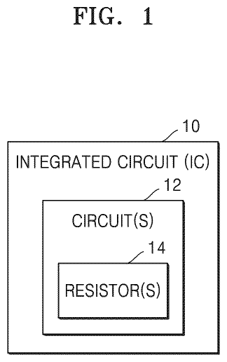

FIG. 1 is a conceptual block diagram illustrating an example of an integrated circuit (IC) 10.

Referring to FIG. 1, the IC 10 includes circuit(s) 12 between some elements. A circuit 12 may include resistors 14 connected to perform, for example, a voltage generation circuit function. In some implementations, the IC 10 may be implemented by a memory device, which may be implemented by any memory among dynamic random access memory (DRAM), flash memory, parameter random access memory (PRAM), static random access memory (SRAM), magnetic random access memory (MRAM), resistive random access memory (RRAM), ferroelectric random access memory (FRAM), high bandwidth memory (HBM), hybrid memory cube (HMC), or the like.

In some implementations, the resistors 14 may be included in a voltage generation circuit and implemented by a plurality of resistors (sometimes, referred to as a resistor ladder or a resistor string) connected between a line of a voltage source voltage (e.g., VDD) and a line of a ground voltage (e.g., VSS). The resistors 14 may divide between the voltage source voltage VDD level and the ground voltage VSS level into certain voltage differences and output divided voltage levels.

In some implementations, each of the voltage levels distributed by the resistors 14 may be provided as a reference voltage to a circuit 12 configured to perform a comparison function. A comparison circuit may determine the logic level of an input signal by comparing the voltage level of the input signal to a reference voltage level.

In some implementations, the resistors 14 may be included in an analog-to-digital converter (ADC) configured to convert an analog signal into a digital signal and may be implemented by a resistor string having the same resistance value. When the resistance values of a plurality of resistors connected in series between a first voltage and a second voltage are identical to each other, the ADC may divide between the first voltage level and the second voltage level into equal voltage differences and provide each of the divided voltage levels to a corresponding comparator, each comparator may output a result obtained by comparing the voltage level of an analog input signal to a corresponding distributed voltage level, and the output result may be encoded to output a digital signal. That is, by providing the voltage between both ends of each resistor to be identical, input and output voltages of the ADC may maintain linearity.

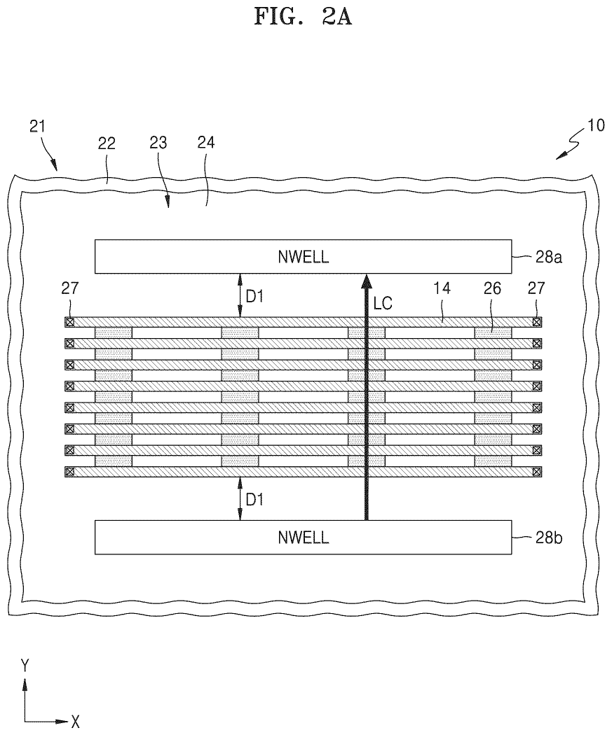

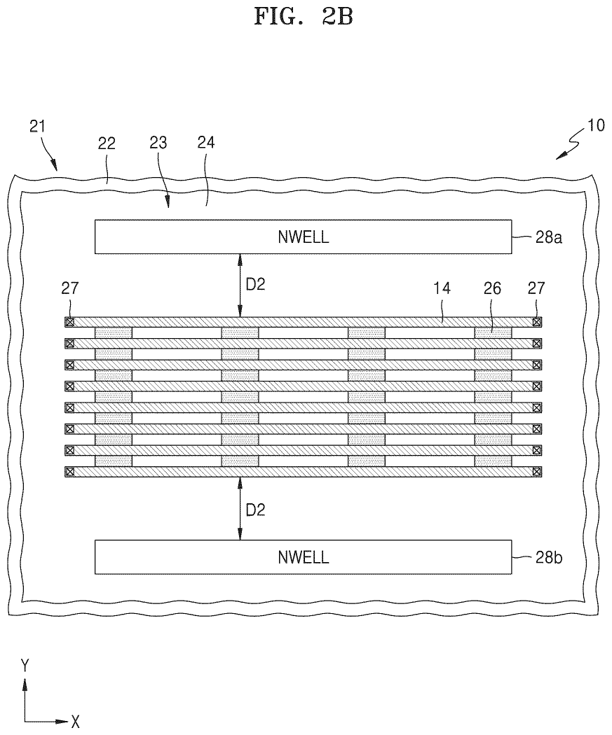

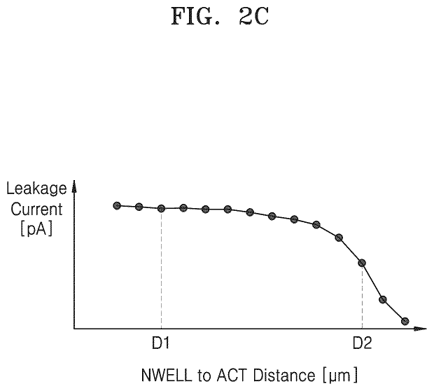

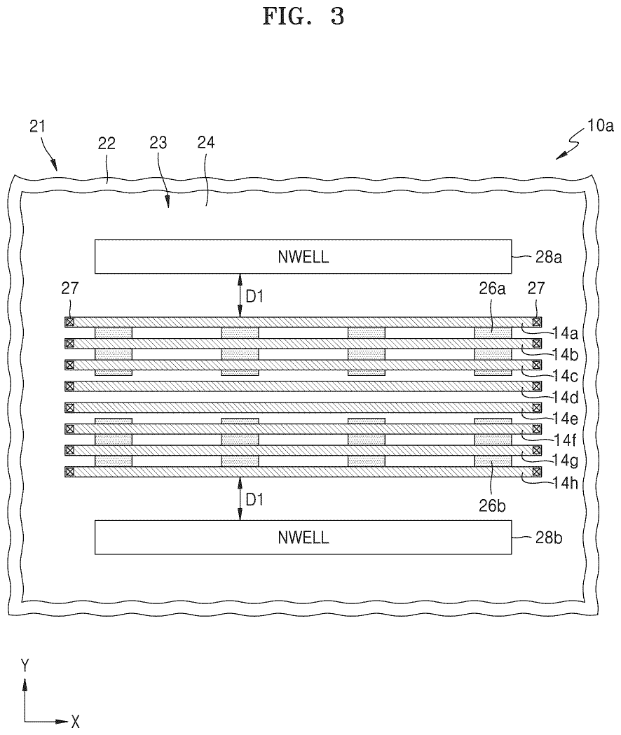

FIGS. 2A, 2B, and 3 are views illustrating an example an IC including polysilicon resistors. FIGS. 2A, 2B, and 3 are top views of ICs 10 and 10a, and FIG. 2C is a graph showing a leakage current characteristic according to the distance between an n-type well, e.g., an Nwell, region and an active region. For convenience of understanding, the terms “upper surface/lower surface, upper portion/lower portion, on/beneath, and the like” are used with reference to directions shown in a referred drawing. Therefore, even the same surface may be differently referred to as an upper surface or a lower surface according to a direction shown in a drawing.

Referring to FIG. 2A, the IC 10 is formed on a semiconductor substrate 21 and the semiconductor substrate 21 may include a semiconductor material 22 extending along an upper surface 23 of the semiconductor substrate 21. The semiconductor material 22 may be, for example, p-type that is a first conductive type. An isolation layer 24 (sometimes, referred to as a field oxide layer) may be formed on the upper surface 23 of the semiconductor substrate 21. Polysilicon resistors 14 may be on, e.g., border in the X and Y direction, the isolation layer 24 and active regions 26 and extend in a first horizontal direction X. The active regions 26 may be defined by the isolation layer 24. The active regions 26 may extend in a second horizontal direction Y that is perpendicular to the first horizontal direction X and have no electrical connection on the semiconductor substrate 21, e.g., each of the active regions 26 are electrically isolated from other components. Contacts 27 may be formed on both ends of the polysilicon resistors 14 to provide an electrical connection to each of the polysilicon resistors 14.

First and second well regions 28a and 28b may be arranged adjacent to the polysilicon resistors 14. The first and second well regions 28a and 28b may be a second conductive type, i.e., n-type wells. Circuit elements of the IC 10 may be in the first and second well regions 28a and 28b, respectively. The first and second well regions 28a and 28b may be spaced apart from the active regions 26 by a first distance D1 in the second horizontal direction Y in which the active regions 26 extend. The circuit elements of the IC 10 may operate to perform given functions. In this case, FIG. 2A shows that a leakage current path LC is formed from the second well region 28b to the first well region 28a through a certain active region 26. On the contrary, a leakage current path LC may be formed from the first well region 28a to the second well region 28b through a certain active region 26. This means that the first distance D1 between the first and second well regions 28a and 28b and the active regions 26 is short enough to form the leakage current path LC.

Referring to FIG. 2B, the first and second well regions 28a and 28b may be spaced apart from the active regions 26 by a second distance D2 in the second horizontal direction Y in which the active regions 26 extend. The second distance D2 may be greater than the first distance D1 of FIG. 2A. Referring to FIG. 2C, a leakage current is relatively low when the distance between the first and second well regions 28a and 28b and the active regions 26 is the second distance D2 compared to when the distance is the first distance D1. The leakage current decreases as the separation distance between the first and second well regions 28a and 28b and the active regions 26 increases, but the chip size of the IC 10 also increases due to the increase in the separation distance therebetween.

Referring to FIG. 3, in the IC 10a, when the separation distance between the first and second well regions 28a and 28b and the active regions 26 is as short as the first distance D1, to block the leakage current path LC formed from the second well region 28b to the first well region 28a through a certain active region 26, active regions 26a and 26b beneath polysilicon resistors 14a to 14h are cut to have the isolation layer 24 therebetween, e.g., the active regions 26a and 26b include discontinuous portions. The leakage current path LC may be removed by the cut active regions 26a and 26b.

For example, the polysilicon resistors 14a to 14h may be designed to have the same resistance value. However, the polysilicon resistors 14d and 14e among the polysilicon resistors 14a to 14h are formed on the isolation layer 24 and the other polysilicon resistors 14a, 14b, 14c, 14f, 14g, and 14h are formed on the active regions 26a and 26b and the isolation layer 24. This means that there exists a mismatch between the resistance values of the polysilicon resistors 14d and 14c and the resistance values of the other polysilicon resistors 14a, 14b, 14c, 14f, 14g, and 14h due to an influence of different patterns (e.g., a case where only the isolation layer 24 exists and a case where the active regions 26a and 26b and the isolation layer 24 exist) beneath the polysilicon resistors 14a to 14h.

In some implementations, erroneous distributed voltage levels output from a voltage generation circuit can occur due to the mismatch of the resistance values of the polysilicon resistors 14a to 14h. For a comparator using a distributed voltage level as a reference voltage level, when the reference voltage level used to determine the voltage level of an input signal is wrong, an error may occur when determining the logic level of the input signal. When the polysilicon resistors 14a to 14h are used in an ADC, input and output voltages of the ADC may not maintain linearity. To reduce mismatch of the resistance values of the polysilicon resistors 14a to 14h, patterns beneath the polysilicon resistors 14a to 14h can have the same surroundings.

Hereinafter, various examples of configurations of polysilicon resistors are described in detail.

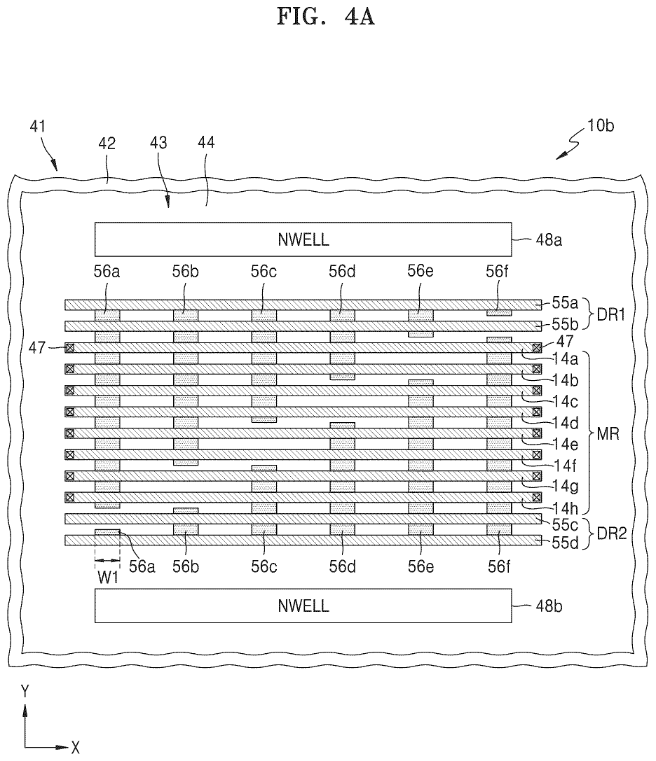

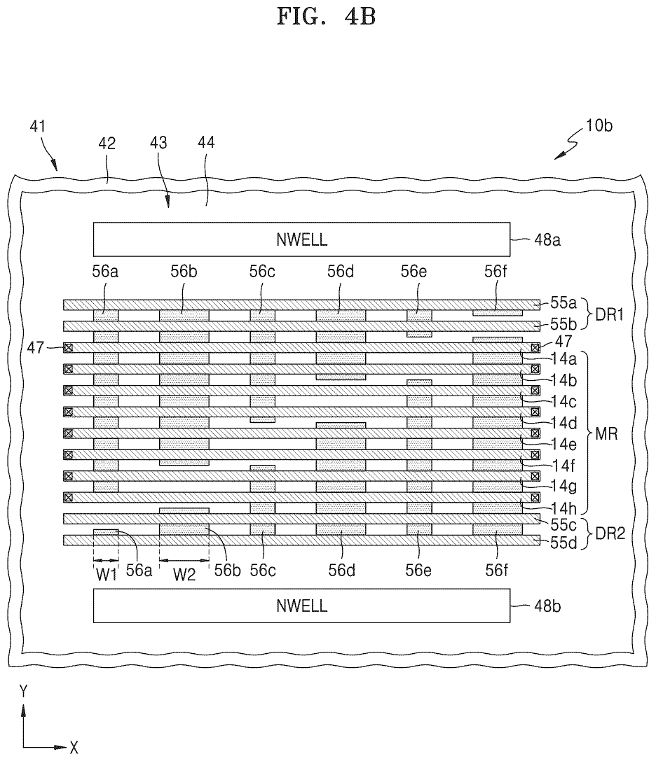

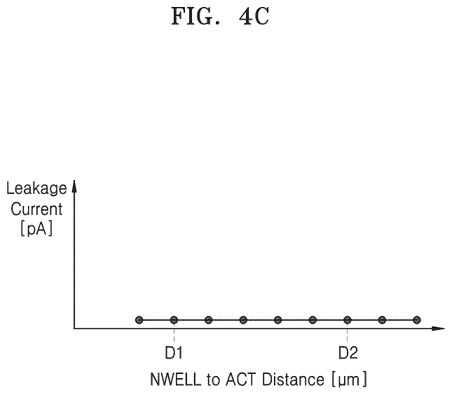

FIGS. 4A and 4B are views illustrating polysilicon resistors. FIGS. 4A and 4B are top views of an IC 10b, and FIG. 4C is a graph showing a leakage current characteristic according to the distance between an Nwell region and an active region.

Referring to FIGS. 1 and 4A, the IC 10b is formed on a semiconductor substrate 41, and the semiconductor substrate 41 includes a semiconductor material 42 extending along an upper surface 43 of the semiconductor substrate 41. The semiconductor material 42 may be, for example, p-type that is the first conductive type. An isolation layer 44 may be formed on the upper surface 43 of the semiconductor substrate 41. Polysilicon resistors 14a to 14h may be on the isolation layer 44 and active regions 56a to 56f and extend in the first horizontal direction X. The boundaries of active regions 56a to 56f may be defined by the isolation layer 44, e.g., the boundaries of isolation layer 44 begins where boundaries of some portions of the active regions 56 end. The active regions 56a to 56f may be cut once while extending in the second horizontal direction Y that is perpendicular to the first horizontal direction X such that the isolation layer 44 is between the cut portions. Additionally, the active regions 56a to 56f may have no electrical connection on the semiconductor substrate 41. Contacts 47 may be formed on both ends of the polysilicon resistors 14a to 14h to provide an electrical connection to each of the polysilicon resistors 14a to 14h.

The polysilicon resistors 14a to 14h are main resistors MR used for an operation of a circuit 12. First and second well regions 48a and 48b may be arranged adjacent to the main resistors MR. The first and second well regions 48a and 48b may be second conductive type, e.g., n-type, wells. Circuit elements of the IC 10b may be in the first and second well regions 48a and 48b, respectively. The first and second well regions 48a and 48b may be spaced apart from the active regions 56a to 56f by the first distance D1 in the second horizontal direction Y in which the active regions 56a to 56f extend.

The IC 10b may include dummy resistors DR1 and DR2 arranged adjacent to the main resistors MR in the second horizontal direction Y. The polysilicon resistors 14a to 14h that are the main resistors MR may be on the isolation layer 44 and the active regions 56a to 56f and extend in the first horizontal direction X. The dummy resistors DR1 and DR2 may include polysilicon resistors 55a to 55d, and the polysilicon resistors 55a to 55d may be on the isolation layer 44 and the active regions 56a to 56f and extend in the first horizontal direction X.

The polysilicon resistors 14a to 14h are electrically connected to the circuit 12, and the dummy resistors DR1 and DR2 are not electrically connected to the circuit 12 and not used in the IC 10b. The dummy resistors DR1 and DR2 can reduce mismatch between the resistance values of the polysilicon resistors 14a to 14h, which may occur due to a semiconductor process difference in the main resistors MR.

The polysilicon resistors 14a and 14b among the main resistors MR overlap five active regions 56a, 56b, 56c, 56d, and 56f in the vertical direction, e.g., the polysilicon resistors 14a and 14b are directly beneath the five active regions 56a, 56b, 56c, 56d, and 56f. The polysilicon resistors 14c and 14d overlap five active regions 56a, 56b, 56c, 56e, and 56f in the vertical direction, e.g., the polysilicon resistors 14c and 14d are directly beneath the five active regions 56a, 56b, 56c, 56d, and 56f. The polysilicon resistors 14e and 14f overlap five active regions 56a, 56b, 56d, 56c, and 56f in the vertical direction, e.g., the polysilicon resistors 14e and 14f are directly beneath the five active regions 56a, 56b, 56c, 56d, and 56f. The polysilicon resistors 14g and 14h overlap five active regions 56a, 56c, 56d, 56c, and 56f in the vertical direction, e.g., the polysilicon resistors 14g and 14h are directly beneath the five active regions 56a, 56b, 56c, 56d, and 56f. Each of the polysilicon resistors 14a to 14h may be arranged to overlap five of the active regions 56a to 56f in the vertical direction. This arrangement ensures that polysilicon resistors 14a to 14h have the same surroundings to reduce a mismatch of the resistance values between the polysilicon resistors 14a to 14h.

The active regions 56a to 56f beneath the polysilicon resistors 14a to 14h may have no electrical connection to the semiconductor substrate 41 and may be cut at least once while extending with a first width W1 in the second horizontal direction Y that is perpendicular to the first horizontal direction X. The isolation layer 44 may be formed and interposed in at least one cut region in each of the active regions 56a to 56f. As a result, a leakage current path is blocked by the at least one cut region in each of the active regions 56a to 56f, and because the spacing between the first and second well regions 48a and 48b and the active regions 56a to 56f may be reduced by blocking the leakage current path, the chip size of the IC 10b may be reduced.

In some implementations, the active regions 56a to 56f beneath the polysilicon resistors 14a to 14h may be cut at least once while extending in the second horizontal direction Y that is perpendicular to the first horizontal direction X. The isolation layer 44 may be formed in at least one cut region in each of the active regions 56a to 56f. Accordingly, the isolation layer 44 may be interposed at least once in each of the active regions 56a to 56f.

Referring to FIG. 4B, the active regions 56a to 56f beneath the polysilicon resistors 14a to 14h have different widths and are cut at least once. For example, each of the active regions 56a, 56c, and 56e may have the first width W1 and be separated by the isolation layer 44 in a cut region and each of the active regions 56b, 56d, and 56f may have a second width W2 that is greater than the first width W1 and be separated by the isolation layer 44 in a cut region.

Referring to FG. 4C, a leakage current hardly flows even though the first distance D1 is a short distance between the first and second well regions 48a and 48b and the active regions 56a to 56f and the second distance D2 is a long distance between the first and second well regions 48a and 48b and the active regions 56a to 56f. FIG. 4C demonstrates that a leakage current path is blocked by the at least one cut region in each of the active regions 56a to 56f, and because the spacing between the first and second well regions 48a and 48b and the active regions 56a to 56f may be reduced by blocking the leakage current path, the chip size of the IC 10b may be reduced.

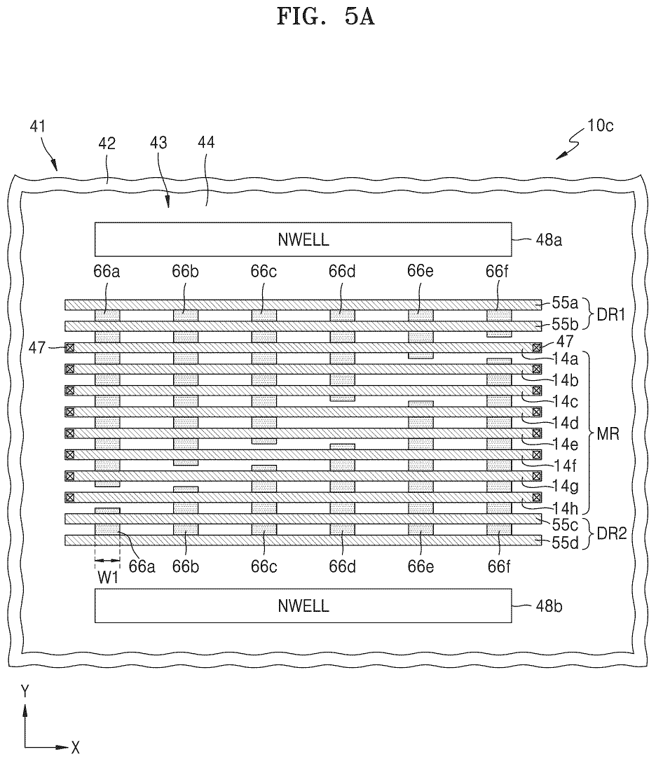

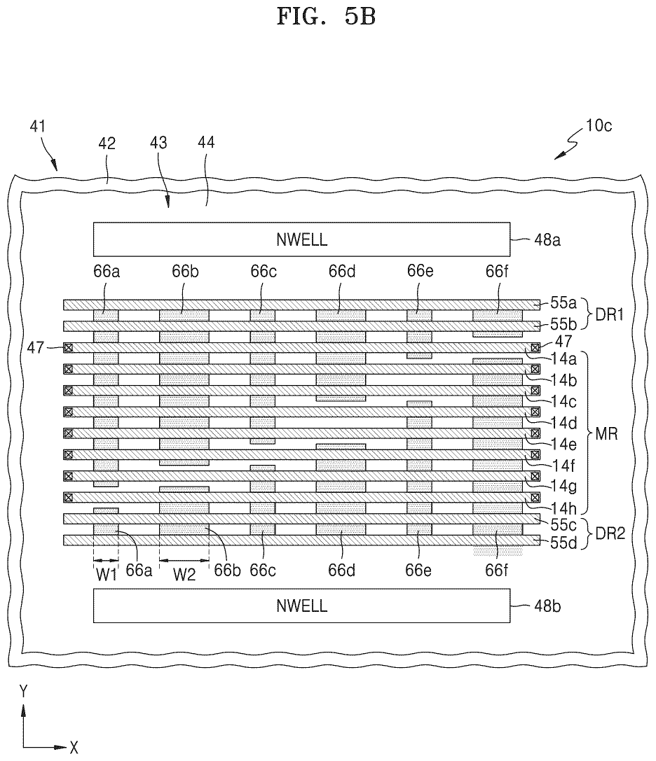

FIGS. 5A and 5B are views illustrating examples of polysilicon resistors. FIGS. 5A and 5B are top views of an IC 10c. Hereinafter, the description of the polysilicon resistors 14a to 14h made with reference to FIG. 4A will not be repeated for the remaining figures.

Referring to FIG. 5A, the IC 10c includes the dummy resistors DR1 and DR2 arranged adjacent to the main resistors MR in the second horizontal direction Y. The polysilicon resistors 14a to 14h that are the main resistors MR may be on the isolation layer 44 and active regions 66a to 66f and extend in the first horizontal direction X. The dummy resistors DR1 and DR2 may include the polysilicon resistors 55a to 55d, and the polysilicon resistors 55a to 55d may be on the isolation layer 44 and the active regions 66a to 66f and extend in the first horizontal direction X. The dummy resistors DR1 and DR2 can reduce mismatch between the resistance values of the polysilicon resistors 14a to 14h, which may occur due to a semiconductor process difference in the main resistors MR.

The polysilicon resistor 14a among the main resistors MR overlaps five active regions 66a, 66b, 66c, 66d, and 66e in the vertical direction. The polysilicon resistors 14b and 14c overlap five active regions 66a, 66b, 66c, 66d, and 66f in the vertical direction. The polysilicon resistors 14d and 14c overlap five active regions 66a, 66b, 66c, 66e, and 66f in the vertical direction. The polysilicon resistor 14f overlaps five active regions 66a, 66b, 66d, 66e, and 66f in the vertical direction. The polysilicon resistor 14g overlaps five active regions 66a, 66c, 66d, 66e, and 66f in the vertical direction. The polysilicon resistor 14h overlaps five active regions 66b, 66c, 66d, 66c, and 66f in the vertical direction. Each of the polysilicon resistors 14a to 14h may be arranged to overlap five of the active regions 66a to 66f in the vertical direction, which can reduce the mismatch between the resistance values of the polysilicon resistors 14a to 14h.

The active regions 66a to 66f beneath the polysilicon resistors 14a to 14h may have no electrical connection on the semiconductor substrate 41 and may be cut at least once while extending with the first width W1 in the second horizontal direction Y that is perpendicular to the first horizontal direction X. The isolation layer 44 may be formed and interposed in at least one cut region in each of the active regions 66a to 66f. This means that a leakage current path is blocked by the at least one cut region in each of the active regions 66a to 66f. As a result of the spacing between the first and second well regions 48a and 48b and the active regions 66a to 66f being reduced by blocking the leakage current path, the chip size of the IC 10c may be reduced.

Referring to FIG. 5B, the active regions 66a to 66f beneath the polysilicon resistors 14a to 14h have different widths and are cut at least once. For example, each of the active regions 66a, 66c, and 66e have the first width W1 and be separated by the isolation layer 44 in a cut region and each of the active regions 66b, 66d, and 66f may have the second width W2 that is greater than the first width W1 and be separated by the isolation layer 44 in a cut region.

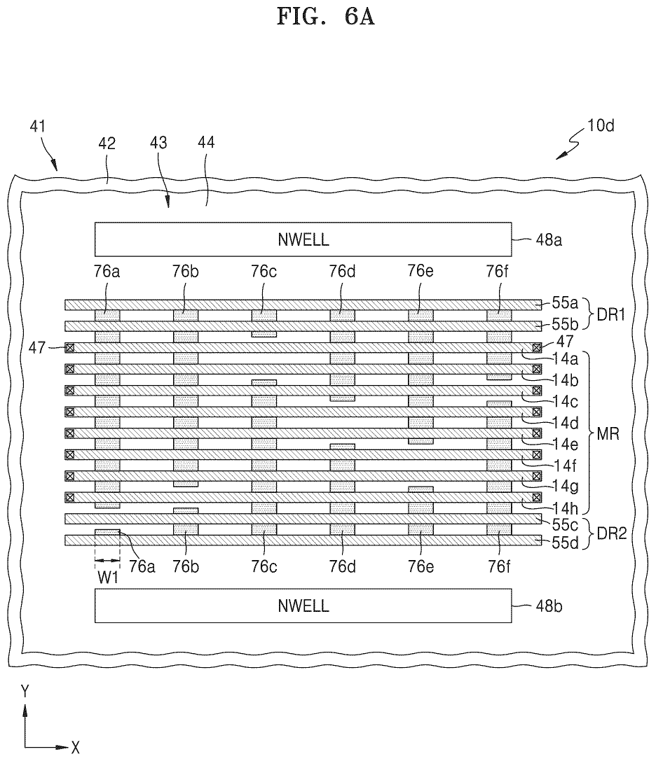

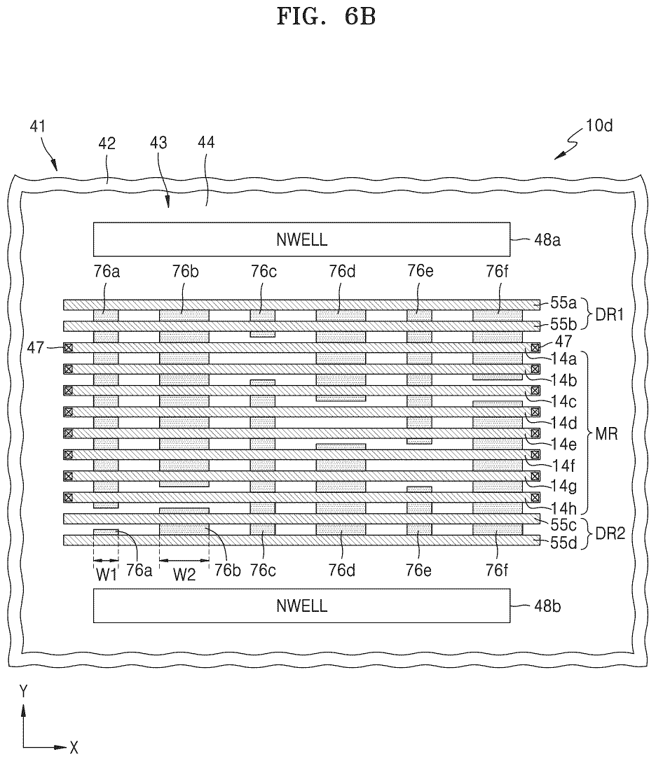

FIGS. 6A and 6B are views illustrating examples of polysilicon resistors. FIGS. 6A and 6B are top views of an IC 10d. Hereinafter, repeated description of the polysilicon resistors 14a to 14h made with reference to FIGS. 4A and 5A is omitted herein.

Referring to FIG. 6A, the IC 10d includes the dummy resistors DR1 and DR2 arranged adjacent to the main resistors MR in the second horizontal direction Y. The polysilicon resistors 14a to 14h that are the main resistors MR may be on the isolation layer 44 and active regions 76a to 76f and extend in the first horizontal direction X. The dummy resistors DR1 and DR2 may include the polysilicon resistors 55a to 55d, and the polysilicon resistors 55a to 55d may be on the isolation layer 44 and the active regions 76a to 76f and extend in the first horizontal direction X. The dummy resistors DR1 and DR2 may be provided to prevent a mismatch of the resistance values of the polysilicon resistors 14a to 14h, which may occur due to a semiconductor process difference in the main resistors MR.

The polysilicon resistors 14a and 14b among the main resistors MR overlap five active regions 76a, 76b, 76d, 76c, and 76f in the vertical direction. The polysilicon resistor 14c overlaps five active regions 76a, 76b, 76c, 76d, and 76e in the vertical direction. The polysilicon resistors 14d and 14e overlap five active regions 76a, 76b, 76c, 76e, and 76f in the vertical direction. The polysilicon resistors 14f and 14g overlap five active regions 76a, 76b, 76c, 76d, and 76f in the vertical direction. The polysilicon resistor 14h overlaps five active regions 76a, 76c, 76d, 76e, and 76f in the vertical direction. Each of the polysilicon resistors 14a to 14h may be arranged to overlap five of the active regions 76a to 76f in the vertical direction. This arrangement ensures that the polysilicon resistors 14a to 14h have the same surroundings to reduce mismatch of the resistance values of the polysilicon resistors 14a to 14h.

The active regions 76a to 76f beneath the polysilicon resistors 14a to 14h may have no electrical connection on the semiconductor substrate 41 and may be cut at least once while extending with the first width W1 in the second horizontal direction Y that is perpendicular to the first horizontal direction X. The isolation layer 44 may be formed and interposed in at least one cut region in each of the active regions 76a to 76f. This means that a leakage current path is blocked by the at least one cut region in each of the active regions 76a to 76f, and because the spacing between the first and second well regions 48a and 48b and the active regions 76a to 76f may be reduced by blocking the leakage current path, the chip size of the IC 10d may be reduced.

Referring to FIG. 6B, the active regions 76a to 76f beneath the polysilicon resistors 14a to 14h may have different widths and are cut at least once. For example, each of the active regions 76a, 76c, and 76e may have the first width W1 and be separated by the isolation layer 44 in a cut region and each of the active regions 76b, 76d, and 76f may have the second width W2 that is greater than the first width W1 and be separated by the isolation layer 44 in a cut region.

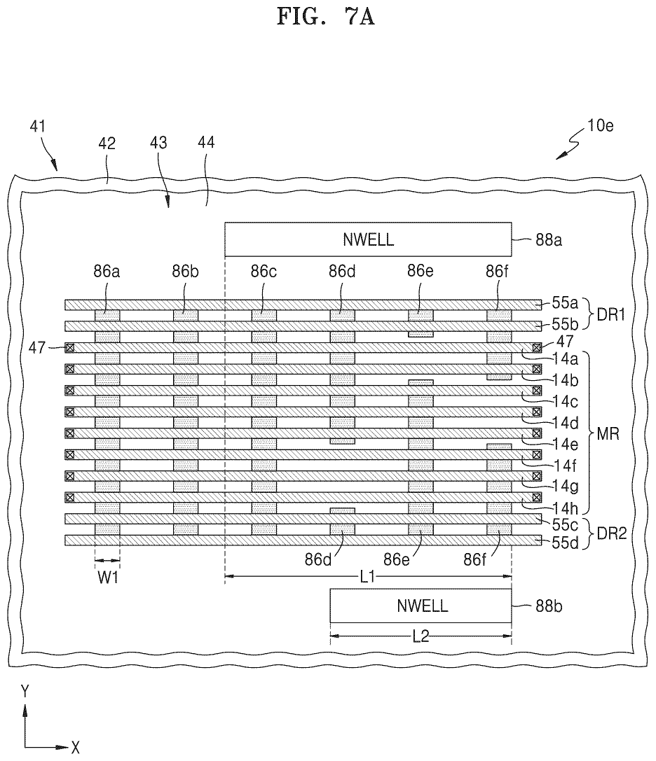

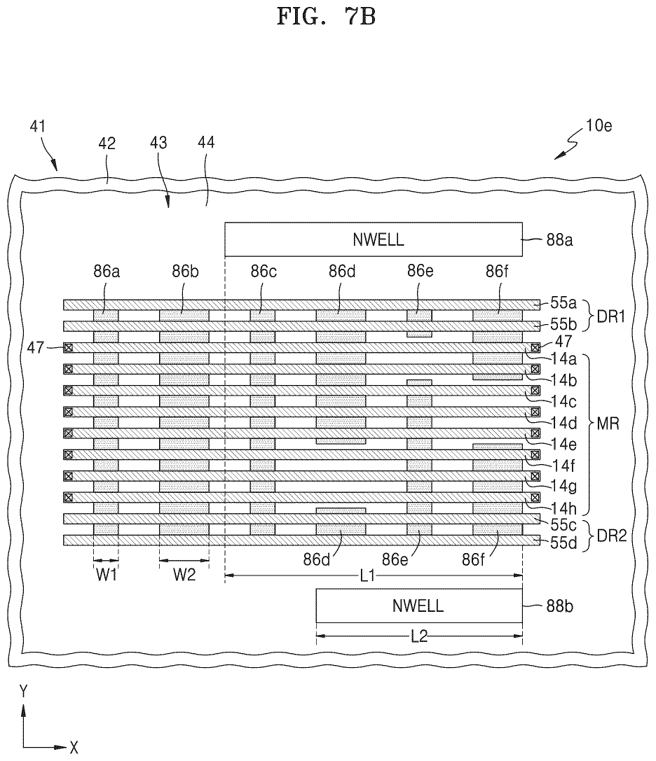

FIGS. 7A and 7B are views illustrating examples of polysilicon resistors. FIGS. 7A and 7B are top views of an IC 10e. Hereinafter, the description of the polysilicon resistors 14a to 14h made with reference to FIGS. 4A and 5A is omitted herein.

Referring to FIG. 7A, the IC 10e includes the dummy resistors DR1 and DR2 arranged adjacent to the main resistors MR in the second horizontal direction Y. The polysilicon resistors 14a to 14h that are the main resistors MR may be on the isolation layer 44 and active regions 86a to 86f and extend in the first horizontal direction X. The dummy resistors DR1 and DR2 may include the polysilicon resistors 55a to 55d, and the polysilicon resistors 55a to 55d may be on the isolation layer 44 and the active regions 86a to 86f and extend in the first horizontal direction X. The dummy resistors DR1 and DR2 reduce mismatch between the resistance values of the polysilicon resistors 14a to 14h, which may occur due to a semiconductor process difference in the main resistors MR.

The polysilicon resistors 14a and 14b among the main resistors MR overlap five active regions 86a, 86b, 86c, 86d, and 86f in the vertical direction. The polysilicon resistors 14c, 14d, and 14e overlap five active regions 86a, 86b, 86c, 86d, and 86e in the vertical direction. The polysilicon resistors 14f, 14g, and 14h overlap five active regions 86a, 86b, 86c, 86c, and 86f in the vertical direction. Each of the polysilicon resistors 14a to 14h may be arranged to overlap five of the active regions 86a to 86f in the vertical direction. This arrangement ensures the polysilicon resistors 14a to 14h have the same surroundings to reduce a mismatch of the resistance values of the polysilicon resistors 14a to 14h.

First and second well regions 88a and 88b may be arranged adjacent to the dummy resistors DR1 and DR2. The first and second well regions 88a and 88b may be second conductive type, i.e., n-type, wells. Circuit elements of the IC 10c may be in the first and second well regions 88a and 88b, respectively. The first well region 88a may extend by a first length L1 in the first horizontal direction X, and the second well region 88b may extend by a second length L2 in the first horizontal direction X. In the present example, the first and second well regions 88a and 88b horizontally overlap each other by the second length L2. In the present example, the active regions 86a to 86f may have no electrical connection on the semiconductor substrate 41 and three active regions 86d, 86c, and 86f among the active regions 86a to 86f may be within the second length L2 by which the first and second well regions 88a and 88b horizontally overlap each other.

When the distance between the first and second well regions 88a and 88b and the active regions 86d, 86e, and 86f is short, a leakage current path from the second well region 88b to the first well region 88a through any of the active regions 86d, 86e, and 86f or a leakage current path from the first well region 88a to the second well region 88b through any of the active regions 86d, 86e, and 86f may be formed. To block such a leakage current path, the active regions 86d, 86c, and 86f beneath the polysilicon resistors 14a to 14h may be cut at least once while extending with the first width W1 in the second horizontal direction Y. The isolation layer 44 may be formed and interposed in at least one cut region in each of the active regions 86d, 86e, and 86f. This means that a leakage current path is blocked by the at least one cut region in each of the active regions 86d, 86c, and 86f, and because the spacing between the first and second well regions 88a and 88b and the active regions 86d, 86e, and 86f may be reduced by blocking the leakage current path, the chip size of the IC 10e may be reduced.

Referring to FIG. 7B, the active regions 86a to 86f beneath the polysilicon resistors 14a to 14h have different widths and are cut at least once. For example, the active regions 86a, 86c, and 86e may have the first width W1, the active region 86e may be separated by the isolation layer 44 in a cut region, the active regions 86b, 86d, and 86f may have the second width W2 that is greater than the first width W1, and each of the active regions 86d and 86f may be separated by the isolation layer 44 in a cut region.

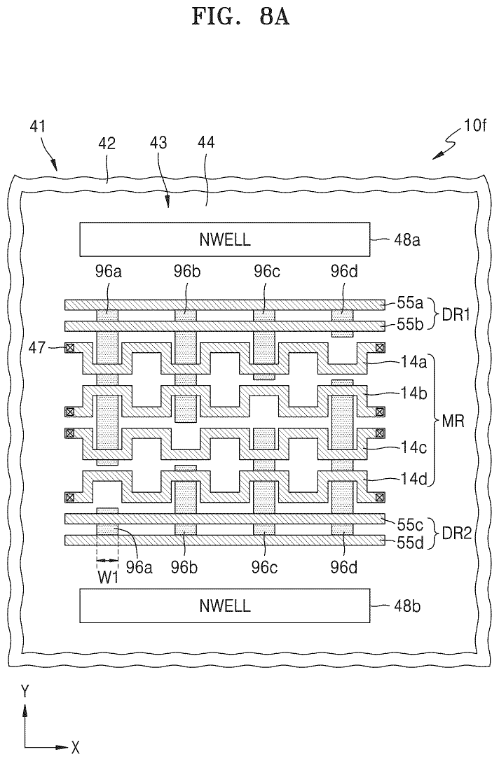

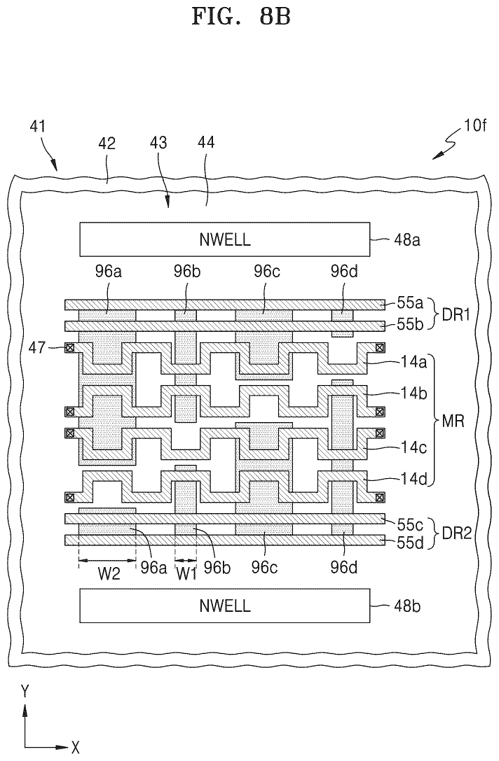

FIGS. 8A and 8B are views illustrating examples of polysilicon resistors. FIGS. 8A and 8B are top views of an IC 10f. Hereinafter, the description of the polysilicon resistors 14a to 14d made with reference to FIGS. 4A and 5A is omitted herein.

Referring to FIG. 8A, the IC 10f includes the dummy resistors DR1 and DR2 arranged adjacent to the main resistors MR in the second horizontal direction Y. The polysilicon resistors 14a to 14d that are the main resistors MR may be on the isolation layer 44 and active regions 96a to 96d and extend in the first horizontal direction X. The dummy resistors DR1 and DR2 may include the polysilicon resistors 55a to 55d, and the polysilicon resistors 55a to 55d may be on the isolation layer 44 and the active regions 96a to 96d and extend in the first horizontal direction X. The dummy resistors DR1 and DR2 may be provided to prevent a mismatch of the resistance values of the polysilicon resistors 14a to 14d, which may occur due to a semiconductor process difference in the main resistors MR.

Each of the polysilicon resistors 14a to 14d that are the main resistors MR may be formed in a concave-convex structure or a zigzag shape and disposed on the isolation layer 44 and active regions 96a to 96d. The polysilicon resistor 14a among the main resistors MR overlaps three active regions 96a, 96b, and 96c in the vertical direction. The polysilicon resistor 14b overlaps three active regions 96a, 96b, and 96d in the vertical direction. The polysilicon resistor 14c overlaps three active regions 96a, 96c, and 96d in the vertical direction. The polysilicon resistor 14d overlaps three active regions 96b, 96c, and 96d in the vertical direction. Each of the polysilicon resistors 14a to 14d may be arranged to overlap three of the active regions 96a to 96d in the vertical direction. This arrangement ensures that the polysilicon resistors 14a to 14d have the same surroundings to reduce a mismatch of the resistance values of the polysilicon resistors 14a to 14d.

The active regions 96a to 96d beneath the polysilicon resistors 14a to 14d may have no electrical connection on the semiconductor substrate 41 and may be cut at least once while extending with the first width W1 in the second horizontal direction Y. The isolation layer 44 may be formed and interposed in at least one cut region in each of the active regions 96a to 96d. This means that a leakage current path is blocked by the at least one cut region in each of the active regions 96a to 96d, and because the spacing between the first and second well regions 48a and 48b and the active regions 96a to 96d may be reduced by blocking the leakage current path, the chip size of the IC 10f may be reduced.

Referring to FIG. 8B, the active regions 96a to 96d beneath the polysilicon resistors 14a to 14d have different widths and are cut at least once. For example, each of the active regions 96b and 96d may have the first width W1 and be separated by the isolation layer 44 in a cut region and each of the active regions 96a and 96c may have the second width W2 that is greater than the first width W1 and be separated by the isolation layer 44 in a cut region.

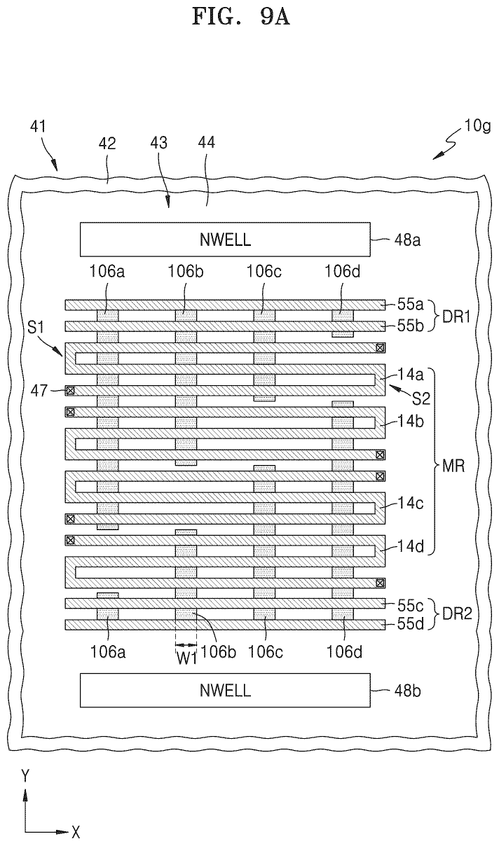

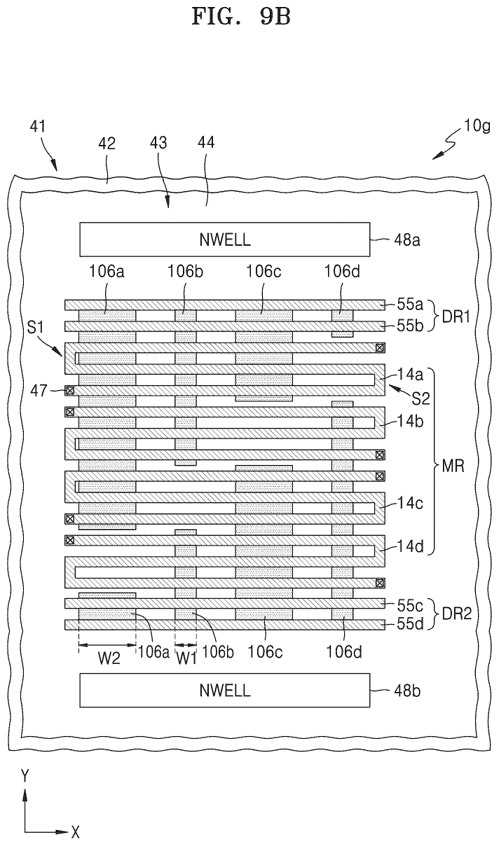

FIGS. 9A and 9B are views illustrating examples of polysilicon resistors. FIGS. 9A and 9B are top views of an IC 10g. Hereinafter, the description of the polysilicon resistors 14a to 14d made with reference to FIGS. 4A and 5A is omitted herein.

Referring to FIG. 9A, the IC 10g may include the dummy resistors DR1 and DR2 arranged adjacent to the main resistors MR in the second horizontal direction Y. The polysilicon resistors 14a to 14d that are the main resistors MR may be on the isolation layer 44 and active regions 106a to 106d and extend in the first horizontal direction X. The dummy resistors DR1 and DR2 may include polysilicon resistors 55a to 55d, and the polysilicon resistors 55a to 55d may be on the isolation layer 44 and the active regions 106a to 106d and extend in the first horizontal direction X. The dummy resistors DR1 and DR2 may be provided to prevent a mismatch of the resistance values of the polysilicon resistors 14a to 14d, which may occur due to a semiconductor process difference in the main resistors MR.

Each of the polysilicon resistors 14a to 14d that are the main resistors MR may have a large resistance value by using a plurality of polysilicon patterns extending in the first horizontal direction X between the contacts 47. The polysilicon resistors 14a to 14d may be implemented by a plurality of polysilicon patterns connected in series to each other at a first side S1 and a second side S2 and disposed on the isolation layer 44 and the active regions 106a to 106d. Among the polysilicon resistors 14a to 14d, the polysilicon resistor 14a overlaps three active regions 106a, 106b, and 106c in the vertical direction. The polysilicon resistor 14b overlaps three active regions 106a, 106b, and 106d in the vertical direction. The polysilicon resistor 14c overlaps three active regions 106a, 106c, and 106d in the vertical direction. The polysilicon resistor 14d overlaps three active regions 106b, 106c, and 106d in the vertical direction. Each of the polysilicon resistors 14a to 14d may be arranged to overlap three of the active regions 106a to 106d in the vertical direction. This arrangement ensures that the polysilicon resistors 14a to 14d have the same surroundings to reduce a mismatch between the resistance values of the polysilicon resistors 14a to 14d.

The active regions 106a to 106d beneath the polysilicon resistors 14a to 14d may have no electrical connection on the semiconductor substrate 41 and may be cut at least once while extending with the first width W1 in the second horizontal direction Y. The isolation layer 44 may be formed and interposed in at least one cut region in each of the active regions 106a to 106d. This means that a leakage current path is blocked by the at least one cut region in each of the active regions 106a to 106d, and because the spacing between the first and second well regions 48a and 48b and the active regions 106a to 106d may be reduced by blocking the leakage current path, the chip size of the IC 10g may be reduced.

Referring to FIG. 9B, the active regions 106a to 106d beneath the polysilicon resistors 14a to 14d have different widths and are cut at least once. For example, each of the active regions 106b and 106d may have the first width W1 and be separated by the isolation layer 44 in a cut region and each of the active regions 106a and 106c may have the second width W2 that is greater than the first width W1 and be separated by the isolation layer 44 in a cut region.

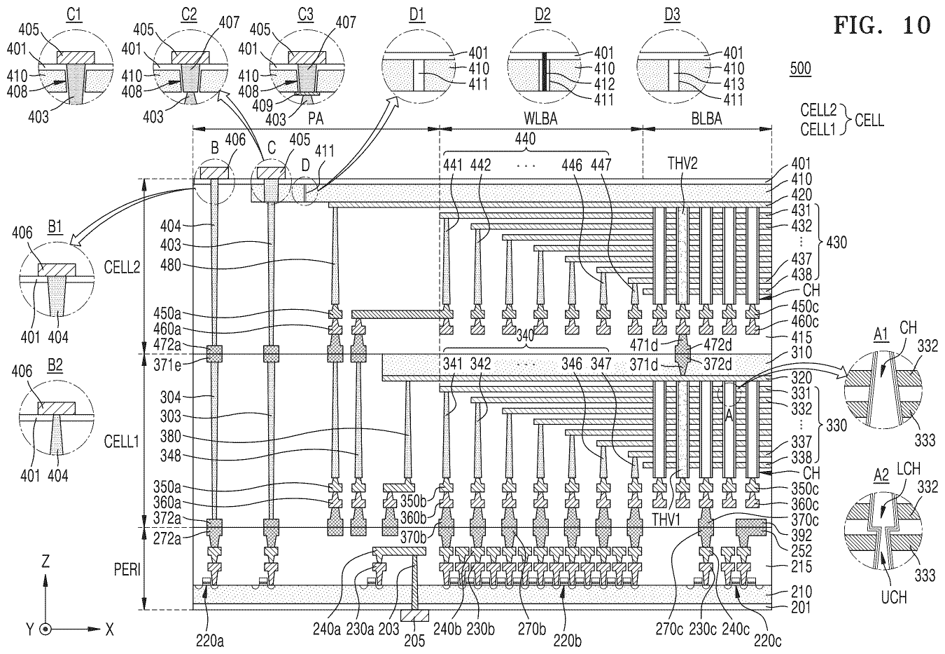

FIG. 10 is a view illustrating an example of a memory device 500.

Referring to FIG. 10, the memory device 500 may have a chip-to-chip (C2C) structure. At least one upper chip including a cell region and a lower chip including a peripheral circuit region PERI may be manufactured separately. Then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu-Cu bonding method. Alternatively, the bonding metal patterns may be formed of aluminum (Al) or tungsten (W).

The memory device 500 may include the at least one upper chip including the cell region. For example, as illustrated in FIG. 10, the memory device 500 may include two upper chips. However, the number of upper chips is not limited thereto. In the case in which the memory device 500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 10. However, other implementations are possible. In some implementations, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines electrically connected to the plurality of circuit elements 220a, 220b, and 220c may be provided in the interlayer insulating layer 215. For example, the plurality of metal lines may include first metal lines 230a, 230b, and 230c connected to the plurality of circuit elements 220a, 220b, and 220c, and second metal lines 240a, 240b, and 240c formed on the first metal lines 230a, 230b, and 230c. The plurality of metal lines may be formed of at least one of various conductive materials. For example, the first metal lines 230a, 230b, and 230c may be formed of tungsten having a relatively high electrical resistivity, and the second metal lines 240a, 240b, and 240c may be formed of copper having a relatively low electrical resistivity.

In some implementations, at least one or more additional metal lines may further be formed on the second metal lines 240a, 240b and 240c. In this case, the second metal lines 240a, 240b and 240c may be formed of aluminum, and at least some of the additional metal lines formed on the second metal lines 240a, 240b and 240c may be formed of copper having an electrical resistivity lower than that of aluminum of the second metal lines 240a, 240b, and 240c.

The interlayer insulating layer 215 may be disposed on the first substrate 210 and may include an insulating material such as silicon oxide and/or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (e.g., the Z-axis direction) perpendicular to a top surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked on the third substrate 410 in a direction (e.g., the Z-axis direction) perpendicular to a top surface of the third substrate 410. Each of the second substrate 310 and the third substrate 410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some implementations, as illustrated in a region ‘A1’, the channel structure CH may be provided in the bit line bonding region BLBA and may extend in the direction perpendicular to the top surface of the second substrate 310 to penetrate the word lines 330, the string selection lines, and the ground selection line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and also referred to as a bit line and may be connected to the channel structure CH through the first metal line 350c. The bit line 360c may extend in a first direction (e.g., a Y-axis direction) parallel to the top surface of the second substrate 310.

In some implementations, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines 333 to 338. The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, forming a channel having a substantially uniform width can increase in difficulty. In this example, the memory device 500 includes a channel having improved width uniformity due to the lower channel LCH and the upper channel UCH that are sequentially formed.

When the channel structure CH includes the lower channel LCH and the upper channel UCH as illustrated in the region ‘A2’, a word line located near to a boundary between the lower channel LCH and the upper channel UCH may be a dummy word line. For example, the word lines 332 and 333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, which can reduce an influence of a non-uniform channel width between the lower and upper channels LCH and UCH on an operation of the memory device.

In addition, the number of the lower word lines (e.g., 331 and 332) penetrated by the lower channel LCH is less than the number of the upper word lines (e.g., 333 to 338) penetrated by the upper channel UCH in the region ‘A2’. However, other implementations are possible. In some implementations, the number of lower word lines penetrated by the lower channel LCH may be equal to or more than the number of upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 10, the first through-electrode THV1 may penetrate the common source line 320 and the plurality of word lines 330. In some implementations, the first through-electrode THV1 may further penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other by the bonding method.

In addition, in the bit line bonding region BLBA, an upper metal pattern 252 may be formed in an uppermost metal layer of the peripheral circuit region PERI, and an upper metal pattern 392 having the same shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Referring to FIG. 10, in the word line bonding region WLBA, the word lines 330 of the first cell region CELL1 may extend in a second direction (e.g., an X-axis direction) parallel to the top surface of the second substrate 310 and may be connected to a plurality of cell contact plugs 340 (341 to 347). First metal lines 350b and second metal lines 360b may be sequentially connected onto the cell contact plugs 340 connected to the word lines 330. In the word line bonding region WLBA, the cell contact plugs 340 may be connected to the peripheral circuit region PERI through upper bonding metal patterns 370b of the first cell region CELL1 and upper bonding metal patterns 270b of the peripheral circuit region PERI.

The cell contact plugs 340 may be electrically connected to a row decoder included in the peripheral circuit region PERI. For example, some of the circuit elements 220b of the peripheral circuit region PERI may constitute the row decoder, and the cell contact plugs 340 may be electrically connected to the circuit elements 220b constituting the row decoder through the upper bonding metal patterns 370b of the first cell region CELL1 and the upper bonding metal patterns 270b of the peripheral circuit region PERI. In some implementations, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Likewise, in the word line bonding region WLBA, the word lines 430 of the second cell region CELL2 may extend in the second direction (e.g., the X-axis direction) parallel to the top surface of the third substrate 410 and may be connected to a plurality of cell contact plugs 440 (441 to 447). The cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1, and the upper bonding metal patterns 270b may be formed in the peripheral circuit region PERI. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of aluminum, copper, or tungsten.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material such as a metal, a metal compound, and/or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

Input/output pads 205, 405, and 406 may be disposed in the external pad bonding region PA. Referring to FIG. 10, a lower insulating layer 201 covers a bottom surface of the first substrate 210, and the first input/output pad 205 may be formed on the lower insulating layer 201. The first input/output pad 205 may be connected to at least one of a plurality of the circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 to electrically isolate the first input/output contact plug 203 from the first substrate 210.

An upper insulating layer 401 covering a top surface of the third substrate 410 may be formed on the third substrate 410. The second input/output pad 405 and/or the third input/output pad 406 may be disposed on the upper insulating layer 401. The second input/output pad 405 may be connected to at least one circuit element of the plurality of circuit elements 220a disposed in the peripheral circuit region PERI through second input/output contact plugs 403 and 303, and the third input/output pad 406 may be connected to at least one of the plurality of circuit elements 220a disposed in the peripheral circuit region PERI through third input/output contact plugs 404 and 304.

In some implementations, the third substrate 410 is not disposed in a region in which the input/output contact plug is disposed. For example, as illustrated in a region ‘B’, the third input/output contact plug 404 may be separated from the third substrate 410 in a direction parallel to the top surface of the third substrate 410 and may penetrate an interlayer insulating layer 415 of the second cell region CELL2 so as to be connected to the third input/output pad 406. In this case, the third input/output contact plug 404 may be formed by at least one of various processes.

In some implementations, as illustrated in a region ‘B1’, the third input/output contact plug 404 extends in a third direction (e.g., the Z-axis direction), and a diameter of the third input/output contact plug 404 may become progressively greater toward the upper insulating layer 401. In other words, a diameter of the channel structure CH described in the region ‘A1’ may become progressively less toward the upper insulating layer 401, but the diameter of the third input/output contact plug 404 may become progressively greater toward the upper insulating layer 401. For example, the third input/output contact plug 404 may be formed after the second cell region CELL2 and the first cell region CELL1 are bonded to each other by the bonding method.

In some implementations, as illustrated in a region ‘B2’, the third input/output contact plug 404 may extend in the third direction (e.g., the Z-axis direction), and a diameter of the third input/output contact plug 404 may become progressively less toward the upper insulating layer 401. In other words, like the channel structure CH, the diameter of the third input/output contact plug 404 may become progressively less toward the upper insulating layer 401. For example, the third input/output contact plug 404 may be formed together with the cell contact plugs 440 before the second cell region CELL2 and the first cell region CELL1 are bonded to each other.

In some implementations, the input/output contact plug may overlap with the third substrate 410. For example, as illustrated in a region ‘C’, the second input/output contact plug 403 may penetrate the interlayer insulating layer 415 of the second cell region CELL2 in the third direction (e.g., the Z-axis direction) and may be electrically connected to the second input/output pad 405 through the third substrate 410. In this case, a connection structure of the second input/output contact plug 403 and the second input/output pad 405 may be realized by various methods.

In some implementations, as illustrated in a region ‘C1’, an opening 408 may be formed to penetrate the third substrate 410, and the second input/output contact plug 403 may be connected directly to the second input/output pad 405 through the opening 408 formed in the third substrate 410. In this case, as illustrated in the region ‘C1’, a diameter of the second input/output contact plug 403 may become progressively greater toward the second input/output pad 405. However, other implementations are possible, and the diameter of the second input/output contact plug 403 may become progressively less toward the second input/output pad 405.

In some implementations, as illustrated in a region ‘C2’, the opening 408 penetrating the third substrate 410 may be formed, and a contact 407 may be formed in the opening 408. An end of the contact 407 may be connected to the second input/output pad 405, and another end of the contact 407 may be connected to the second input/output contact plug 403. Thus, the second input/output contact plug 403 may be electrically connected to the second input/output pad 405 through the contact 407 in the opening 408. In this case, as illustrated in the region ‘C2’, a diameter of the contact 407 may become progressively greater toward the second input/output pad 405, and a diameter of the second input/output contact plug 403 may become progressively less toward the second input/output pad 405. For example, the second input/output contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

In some implementations illustrated in a region ‘C3’, a stopper 409 may further be formed on a bottom end of the opening 408 of the third substrate 410, as compared with the examples in the region ‘C2’. The stopper 409 may be a metal line formed in the same layer as the common source line 420. Alternatively, the stopper 409 may be a metal line formed in the same layer as at least one of the word lines 430. The second input/output contact plug 403 may be electrically connected to the second input/output pad 405 through the contact 407 and the stopper 409.

Like the second and third input/output contact plugs 403 and 404 of the second cell region CELL2, a diameter of each of the second and third input/output contact plugs 303 and 304 of the first cell region CELL1 may become progressively less toward the lower metal pattern 371e or may become progressively greater toward the lower metal pattern 371c.

In some implementations, a slit 411 may be formed in the third substrate 410. For example, the slit 411 may be formed in various locations in the external pad bonding region PA. For example, as illustrated in a region ‘D’, the slit 411 may be located between the second input/output pad 405 and the cell contact plugs 440 when viewed in a plan view. Alternatively, the second input/output pad 405 may be located between the slit 411 and the cell contact plugs 440 when viewed in a plan view.

In some implementations, as illustrated in a region ‘D1’, the slit 411 may be formed to penetrate the third substrate 410. For example, the slit 411 may be used to prevent the third substrate 410 from being finely cracked when the opening 408 is formed. However, other implementations are possible, and the slit 411 may be formed to have a depth ranging from about 60% to about 70% of a thickness of the third substrate 410.

In some implementations, as illustrated in a region ‘D2’, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

In some implementations, as illustrated in a region ‘D3’, an insulating material 413 may be formed in the slit 411. For example, the insulating material 413 may be used to electrically isolate the second input/output pad 405 and the second input/output contact plug 403 disposed in the external pad bonding region PA from the word line bonding region WLBA. Since the insulating material 413 is formed in the slit 411, it is possible to prevent a voltage provided through the second input/output pad 405 from affecting a metal layer disposed on the third substrate 410 in the word line bonding region WLBA.

In some implementations, the first to third input/output pads 205, 405, and 406 may be selectively formed. For example, the memory device 500 may be realized to include only the first input/output pad 205 disposed on the first substrate 210, to include only the second input/output pad 405 disposed on the third substrate 410, or to include only the third input/output pad 406 disposed on the upper insulating layer 401.

In some implementations, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the bonding process of the peripheral circuit region PERI and the first cell region CELL1, and then, an insulating layer covering a top surface of the common source line 320 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

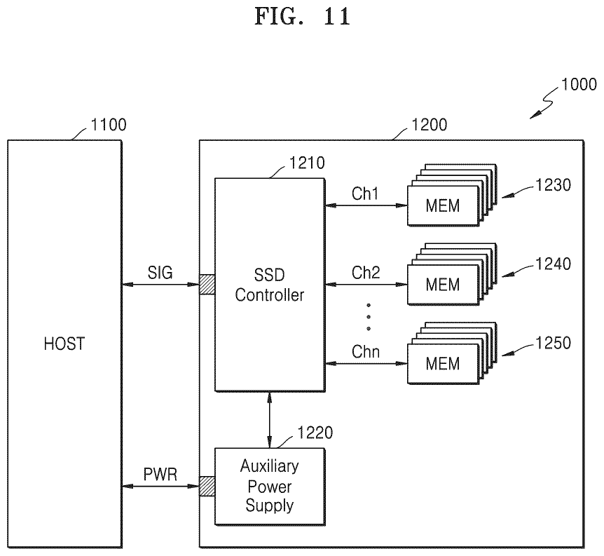

FIG. 11 is a block diagram illustrating an example in which a memory is applied to a solid state driver (SSD) system 1000.

Referring to FIG. 11, the SSD system 1000 may include a host 1100 and an SSD 1200. The SSD 1200 may transmit and receive a signal SIG to and from the host 1100 through a signal connector and receive power PWR from the host 1100 through a power connector. The SSD 1200 may include an SSD controller 1210, an auxiliary power supply 1220, and memory devices 1230, 1240, and 1250. Each of the memory devices 1230, 1240, and 1250 may be a vertical stack type NAND flash memory device. Herein, the SSD 1200 may be implemented using the examples described above with reference to FIGS. 1 to 10.

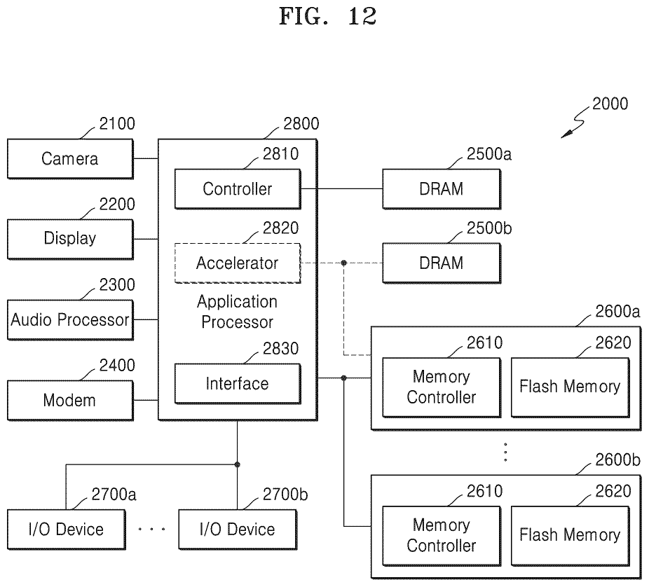

FIG. 12 is a block diagram of a system 2000 illustrating an example of an electronic apparatus including a memory device.

Referring to FIG. 12, the system 2000 may include a camera 2100, a display 2200, an audio processor 2300, a modem 2400, DRAMs 2500a and 2500b, flash memories 2600a and 2600b, input/output (I/O) devices 2700a and 2700b, and an application processor (AP) 2800. The system 2000 may be implemented by a laptop computer, a mobile terminal, a smartphone, a tablet personal computer (PC), a wearable device, a healthcare device, or an Internet of Things (IoT) device. Alternatively, the system 2000 may be implemented by a server or a PC.

The camera 2100 may capture a still image or a moving picture according to control by a user and store the captured image/video data therein or transmit the captured image/video data to the display 2200. The audio processor 2300 may process audio data included in content in the flash memories 2600a and 2600b or from a network. The modem 2400 may modulate and transmit a signal for wired/wireless data transmission and reception and demodulate a signal into an original signal at a reception side. The I/O devices 2700a and 2700b may include devices, such as a universal serial bus (USB), a storage, a digital camera, a secure digital (SD) card, a digital versatile disc (DVD), a network adapter, and a touch screen, configured to provide a digital input and/or output function.

The AP 2800 may control a general operation of the system 2000. The AP 2800 may include a control block 2810, an accelerator block or accelerator chip 2820, and an interface block 2830. The AP 2800 may control the display 2200 to display, on the display 2200, a portion of content stored in the flash memories 2600a and 2600b. If a user input is received through the I/O devices 2700a and 2700b, the AP 2800 may perform a control operation corresponding to the user input. The AP 2800 may include the accelerator chip 2820 that is an exclusive circuit for artificial intelligence (AI) data computation, or the accelerator chip 2820 may be provided separately from the AP 2800. The DRAM 2500b may be additionally mounted in the accelerator block or accelerator chip 2820. An accelerator is a function block configured to perform a particular function of the AP 2800 and may include a graphics processing unit (GPU) that is a function block configured to perform graphics data processing, a neural processing unit (NPU) that is a block configured to professionally perform AI computation and inference, and a data processing unit (DPU) that is a block configured to perform data transmission.

The system 2000 may include a plurality of DRAMs. The AP 2800 may control the DRAMs 2500a and 2500b through a command and a mode register set (MRS) according to a Joint Electron Device Engineering Council (JEDEC) standard or communicate with the DRAMs 2500a and 2500b by setting a DRAM interface protocol to use company-specific functions, such as low voltage/high speed/reliability and the like, and a cyclic redundancy check (CRC)/error correction code (ECC) function. For example, the AP 2800 may communicate with the DRAM 2500a by using an interface, which meets a JEDEC standard, such as low power double data rate 4 (LPDDR4) or LPDDR5, and the accelerator block or accelerator chip 2820 may communicate with the DRAM 2500b by setting a new DRAM interface protocol to control the DRAM 2500b having a higher bandwidth than the DRAM 2500a, the DRAM 2500b being for an accelerator.

Although FIG. 12 shows only the DRAMs 2500a and 2500b, the present example is not limited thereto. Subject to demands for the bandwidth, the reaction speed, and the voltage conditions of the AP 2800 or the accelerator chip 2820, any memory, such as PRAM, SRAM, MRAM, RRAM, FRAM, or hybrid RAM, may be used. The DRAMs 2500a and 2500b have a relatively less latency and bandwidth than the I/O devices 2700a and 2700b or the flash memories 2600a and 2600b. The DRAMs 2500a and 2500b may be initialized at a power-on time point of the system 2000 and used as temporary storage of an operating system and application data by loading the operating system and the application data thereon or used as an execution space of various kinds of software codes.

In the DRAMs 2500a and 2500b, the four fundamental arithmetic operations of addition/subtraction/multiplication/division, a vector operation, an address calculation, or a fast Fourier transform (FFT) operation may be performed. In addition, in the DRAMs 2500a and 2500b, a functional function for execution used for inference may be performed. Herein, inference may be performed by a deep learning algorithm using an artificial neural network. The deep learning algorithm may include a training operation of training a model through various pieces of data and an inference operation of recognizing data by using the trained model. In some implementations, an image captured by a user through the camera 2100 may be signal-processed and stored in the DRAM 2500b, and the accelerator block or accelerator chip 2820 may perform an AI data computation for recognizing data by using data stored in the DRAM 2500b and a function used for inference.

The system 2000 may include a plurality of storages or the flash memories 2600a and 2600b having a greater capacity than the DRAMs 2500a and 2500b. The accelerator block or accelerator chip 2820 may perform the training operation and an AI data computation by using the flash memories 2600a and 2600b. In some implementations, each of the flash memories 2600a and 2600b may include a memory controller 2610 and a flash memory device 2620 and relatively efficiently perform, by using a computation device included in the memory controller 2610, the training operation and an inference AI data computation to be performed by the AP 2800 and/or the accelerator chip 2820. The flash memories 2600a and 2600b may store pictures taken through the camera 2100 or store data received through a data network. For example, augmented reality/virtual reality, high definition (HD), or ultra-high definition (UHD) content may be stored in the flash memories 2600a and 2600b.

Components of the system 2000 may include polysilicon resistors described with reference to FIGS. 1 to 9B. The polysilicon resistors may extend in a second direction that is perpendicular to a first direction in which active regions extend and may be on the active regions and an isolation layer. Each of the polysilicon resistors on the active regions may be configured such that the number of active regions overlapping each polysilicon resistor in the vertical direction is identical. Each of the active regions beneath the polysilicon resistors may be cut at least once in the first direction such that the isolation layer is between the cut portions. When the second conductive type of first and second well regions on the upper surface of the first conductive type of a semiconductor substrate are arranged adjacent to the outer peripheries of the polysilicon resistors, each of active regions overlapping the first and second well regions in the first direction among the active regions beneath the polysilicon resistors may be cut at least once in the first direction such that the isolation layer is between the cut portions. Dummy polysilicon resistors on the upper surface of the semiconductor substrate may be arranged adjacent to the outer peripheries of the polysilicon resistors at both sides of the polysilicon resistors in the first direction. Accordingly, a mismatch of the resistance values of the polysilicon resistors may be prevented and a leakage current path may be blocked to reduce the spacing between circuit devices, thereby reducing the chip size of an IC.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit comprising:
a semiconductor substrate;
active regions on an upper surface of the semiconductor substrate and extending in a first direction;
an isolation layer on the upper surface of the semiconductor substrate and defining boundaries of the active regions and electrically isolating the active regions; and
polysilicon resistors on both the active regions and the isolation layer, the polysilicon resistors extending in a second direction perpendicular to the first direction,
wherein a same number of active regions overlap each of the polysilicon resistors in a vertical direction.

2. The integrated circuit of claim 1, wherein each of the active regions beneath the polysilicon resistors comprises at least one discontinuous portion in the first direction such that the isolation layer is between the discontinuous portions of each of the active regions.

3. The integrated circuit of claim 1, further comprising a dummy polysilicon resistor on the upper surface of the semiconductor substrate and adjacent to an outer periphery of the polysilicon resistors in the first direction.

4. The integrated circuit of claim 3, wherein the dummy polysilicon resistor is electrically isolated from the semiconductor substrate.

5. The integrated circuit of claim 1, wherein the active regions comprise a first active region and a second active region, the first active region has a first width in the second direction, the second active region has a second width in the second direction, and the polysilicon resistors are disposed in the first and second active regions.

6. The integrated circuit of claim 5, wherein the first width of the first active region is the same as the second width of the second active region.

7. The integrated circuit of claim 5, wherein the first width of the first active region is different from the second width of the second active region.

8. An integrated circuit comprising:
a semiconductor substrate of a first conductivity type;
active regions on an upper surface of the semiconductor substrate and extending in a first direction;
an isolation layer on the upper surface of the semiconductor substrate, the isolation layer electrically isolating the active regions and defining boundaries of the active regions;
polysilicon resistors on the active regions and the isolation layer, the polysilicon resistors extending in a second direction that is perpendicular to the first direction; and
a well region of a second conductivity type that is on the upper surface of the semiconductor substrate and arranged adjacent to the active regions, the well region comprising a first well region arranged at a first side of the well region in the first direction and a second well region arranged at a second side of the well region in the first direction,
wherein the active regions beneath the polysilicon resistors comprise first active regions overlapping the first and second well regions in the first direction and second active regions that are a remainder of the active regions, and each of the first active regions is discontinuous such that the isolation layer is disposed between portions of the first active regions in the first direction.

9. The integrated circuit of claim 8, wherein a same number of active regions overlap each of the polysilicon resistors in a vertical direction.

10. The integrated circuit of claim 8, wherein the second active regions beneath the polysilicon resistors are continuous in the first direction and free of the isolation layer.

11. The integrated circuit of claim 8, further comprising a dummy polysilicon resistor on the upper surface of the semiconductor substrate and adjacent to an outer periphery of the polysilicon resistors in the first direction.

12. The integrated circuit of claim 11, wherein the dummy polysilicon resistor is electrically isolated from the semiconductor substrate.

13. The integrated circuit of claim 8, wherein the first active regions and the second active regions have a same width in the second direction.

14. The integrated circuit of claim 8, wherein the first active regions and the second active regions have different widths in the second direction.

15. An integrated circuit comprising:
a semiconductor substrate;
active regions on an upper surface of the semiconductor substrate and extending in a first direction;
an isolation layer on the upper surface of the semiconductor substrate, electrically isolating the active regions, and defining boundaries of the active regions;
polysilicon resistors on the active regions and the isolation layer, the polysilicon resistors extending in a second direction that is perpendicular to the first direction; and
dummy polysilicon resistors disposed, on the upper surface of the semiconductor substrate, at outer peripheries of the polysilicon resistors, and adjacent to both sides of the polysilicon resistors in the first direction,
wherein each of the active regions beneath the polysilicon resistors and the dummy polysilicon resistors comprises at least one discontinuous portion such that the isolation layer is disposed between the discontinuous portions in the first direction.

16. The integrated circuit of claim 15, wherein a same number of active regions overlaps each of the polysilicon resistors in a vertical direction.

17. The integrated circuit of claim 15, wherein the dummy polysilicon resistors are electrically isolated from the semiconductor substrate.

18. The integrated circuit of claim 15, wherein the active regions comprise a first active region and a second active region, the first active region has a first width in the second direction, the second active region has a second width in the second direction, and the polysilicon resistors are disposed in the first and second active regions.

19. The integrated circuit of claim 18, wherein the first width of the first active region is the same as the second width of the second active region.

20. The integrated circuit of claim 18, wherein the first width of the first active region is different from the second width of the second active region.
